(19) United States
(12) Patent Application Publication
(10) Pub. No.: US 2026/0188572 A1
(43) Pub. Date: Jul. 2, 2026

(54) METHOD FOR MANUFACTURING INDUCTORS AND TRANSFORMERS WITH CONTINUOUS WINDING

(71) Applicant: KRAH INDÚSTRIA E COMÉRCIO DE COMPONENTES ELETRÔNICOS LTDA, Timbó, Santa Catarina (SC) (BR)

(72) Inventor: RALPH DA ROCHA FELSMANN, Timbó, Santa Catarina (SC) (BR)

(21) Appl. No.: 18/860,795

(22) PCT Filed: Jun. 28, 2023
(86) PCT No.: PCT/BR2023/050218

§ 371 Date: Oct. 28, 2024

(30) Foreign Application Priority Data
Apr. 29, 2022 (BR) BR1020220083193

(51) Int. Cl. H01F 41/071; G01R 31/72; H01F 41/00; H01F 41/02; H01F 41/10

(52) U.S. Cl. CPC H01F 41/071; G01R 31/72; H01F 41/005; H01F 41/0246; H01F 41/10

(57) ABSTRACT

The present invention belongs to the electrical devices sector, and refers, more specifically, to a manufacturing process of inductors and transformers in general, with continuous winding, with or without an iron/ferrimagnetic core. In relation to the current methods, of individual manufacture, the main innovations of this invention are the reduction of manufacturing costs and agility in the process (greater productivity). The central inventive concept lies in the coiling process on a continuous line for the manufacture of inductors and transformers. In addition to coiling, the processes of core formation, assembly, cutting and electromagnetic testing are part of this continuous manufacturing line. The process for manufacturing inductors and transformers with continuous winding is divided into the following stages: I. Solid Bar Formation (1); II. Continuous Coiling (2); III. Assembly and Fixing of Terminals (3); IV. Cutting and Testing (4); and V. Packaging (5).

### TECHNOLOGICAL SECTOR OF INVENTION

The present invention belongs to the electrical devices sector, and refers, more specifically, to a manufacturing process of inductors and transformers in general, with continuous winding, with or without an iron/ferrimagnetic core.

### STATE OF THE ART

Wire inductors and transformers are currently produced through individual winding processes of each piece. Especially for inductors/transformers with inductance in the order of nano Henry, which operate in the frequency range between MHz and GHz and are mainly used in communication and data computing devices, the individual winding process becomes economically costly and technically challenging due to the small dimensions of the inductors/transformers, in the range of tenths of millimeters.

Current methods winding perform and other processes individually for each manufactured inductor/transformer. This implies more time-consuming, costly and complex processes (mainly due to the low dimensionality of these inductors/transformers), a problem solved by the present invention.

### NEWS OF THE INVENTION

In relation to the current methods, of individual manufacturing, the main innovations of this invention are the reduction of manufacturing costs and agility in the process (greater productivity).

The central inventive concept lies in the winding process on a continuous line for manufacturing inductors and transformers. In addition to coiling, the processes of core formation, assembly, cutting and electromagnetic testing are part of this continuous manufacturing line.

It should be noted that the gains in productivity and reduction in complexity will not negatively impact the quality of the final product, as the continuous manufacturing process ensures high quality/uniformity in winding and electromagnetic properties.

### DESCRIPTION OF THE ATTACHED DRAWINGS

In order for the present invention to be fully understood and put into practice by any technician in this technological sector, it will be described in a clear, concise and sufficient manner, based on the attached drawings, which illustrate and support it listed below:

FIG. 1 represents a diagram with the five steps of the manufacturing process with continuous coiling;

FIG. 2 represents a diagram with the first step of the coiled solid bar forming process;

FIG. 3 represents a scheme with the first stage of the process, with emphasis on the apparatus for ferri/ferromagnetic nuclei;

FIG. 4 represents a diagram with the first step of the process, with emphasis on the case in which glass fibers are dipped in resin and subsequently impregnated with ferri/ferromagnetic material;

FIG. 5 represents a scheme with the first step of the process, with emphasis on the case of the extrusion of ferri/ferromagnetic material;

FIG. 6 represents a diagram with the second step of the continuous winding process with emphasis on the winding of a layer;

FIG. 7 represents a scheme with the second stage of the process, with emphasis on the winding of multiple layers;

FIG. 8 represents a scheme with the second step of the process, highlighting an alternative to the schemes in FIGS. 6 and 7, with a configuration in which spools move around the compacted fiber compacted;

FIG. 9 represents a diagram with the third step of the process of assembling and fixing the terminals;

FIG. 10 represents a scheme with the third step of the process, with emphasis on the design of the terminals, which may vary;

FIG. 11 represents a schematic with the fourth step of the cutting process and testing of continuity and inductance;

FIG. 12 represents a diagram with the fourth step of the process, with emphasis on the continuity and inductance test, an LCR bridge can be used;

FIG. 13 represents a schematic with the fifth step of the packaging process. Detailed description of the invention

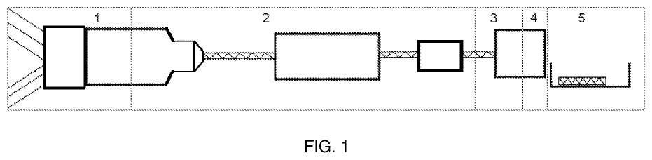

In general, as exemplified in FIG. 1, the process for manufacturing inductors and transformers with continuous winding is divided into the following steps:
1. Formation of the Solid Bar (1);
2. Continuous Winding (2);
3. Assembly and fixing of the Terminals (3);
4. Cutting and Testing (4);
5. Packaging (5).

### First Stage-Solid Bar Formation

Inductors and transformers may have an air core (or a material with magnetic susceptibility close to that of air) or an iron or ferrimagnetic material. The process in this invention includes the production of both inductors/transformers with an air core and ferromagnetic or ferrimagnetic material.

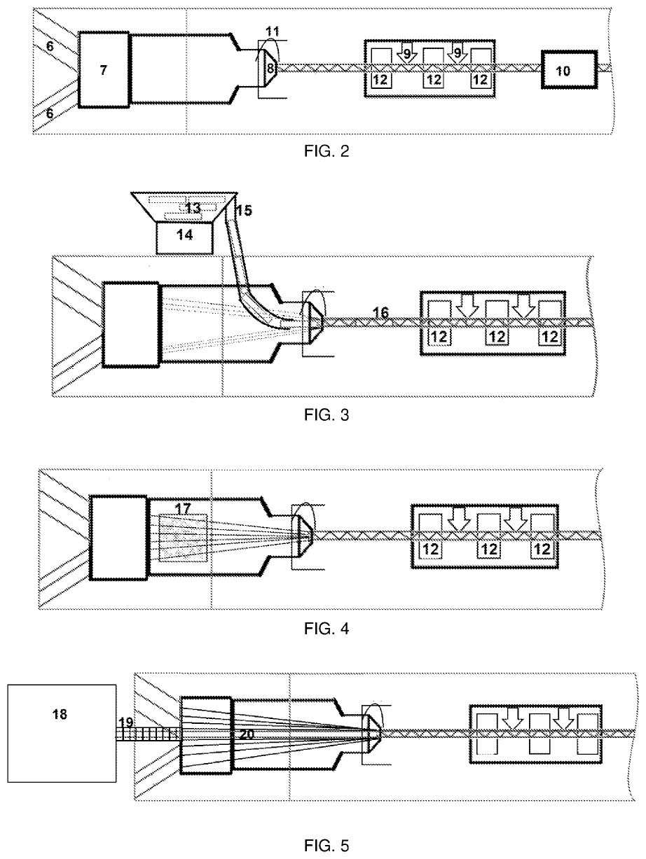

In the case of a core equivalent to air, a solid bar is formed, for example, by compacting glass fibers (6) impregnated with resin (7). The diameter of this bar can be of any value and is determined by specifications of the final application of the component. For example, for the manufacture of inductors/transformers applied in devices operating at frequencies from MHz to GHz, the diameter of the bar is on the order of 1 mm. For the manufacture of bars, it is necessary to use ejector nozzles (8), fixer applicators (resin/varnish) (9) and traction system (10), as shown in FIG. 2. The traction system (10) consists of a motor, gears and belts that drive the bar with a defined speed depending on the product to be manufactured (depending on the diameter or winding pitch, this variable may be different). It is electronically controlled, and can have its speed adjusted, for example, to 300 mm/min, which can vary depending on the part to be manufactured. It is also shown that after impregnation and compaction the wire is wound (11) continuously at the outlet of the ejector nozzle (8). Then the bar with the wire goes through a curing process in the ovens (12) and can be of different quantities depending on the product manufactured (in the example 3 ovens are represented). The temperatures reached are between 150-300° C., but can vary d these limits depending on the part to be manufactured.

For ferri/ferromagnetic nuclei, the apparatus is illustrated in FIG. 3. Previously sintered cylindrical (or parallelepiped) ferrite cores (13) commonly used in the manufacture of inductors/transformers with the individual method can be used. The cores as received are directed through pans (14) and vibrating chutes (15) to be enclosed, for example, by fiberglass. Next, the ferrite and fiberglass core (16) undergoes heat treatment in furnaces (12) so that the fiber forms a rigid layer. The temperatures reached are between 150-300° C., but can vary beyond these limits depending on the part to be manufactured. The steps of impregnation (7) and application of fasteners (9) also occur in this process variant.

Ferri/ferromagnetic nuclei can also be formed on the production line itself by applying grains of the ferri/ferromagnetic material, such grains can be on the scale of microns or nanometers. FIG. 4 presents an example in which glass fibers are dipped in resin and subsequently impregnated with ferri/ferromagnetic material (17). Subsequently, the fibers are compacted and undergo heat treatment in furnaces (12). The temperatures reached are between 150-300° C., but can vary beyond these limits depending on the part to be manufactured. Different material powders can be used, for example, NiZn ferrite and MnZn ferrite. As well as, different powder granulation, temperature and heat treatment time of the powder (e.g., 1000° C. per 1 h), and the concentration per area of magnetic material impregnated in the fiber. The application of fasteners (9) also occurs in this variant of the process.

Another possibility, see FIG. 5, is the extrusion of ferri/ferromagnetic material. Extrusion and sintering (18) of this material in a furnace equipped with a conveyor belt (19) to form a bar that is continuously supplied to the production line (20). This oven must operate at temperatures of around 1000° C. and in some cases can reach 1200° C. During this treatment, a magnetic field can also be applied in a defined direction for alignment of the magnetic domains. The bar goes on to be wrapped by fiberglass and subsequent coiling as previously presented.

### Second Stage-Continuous Winding

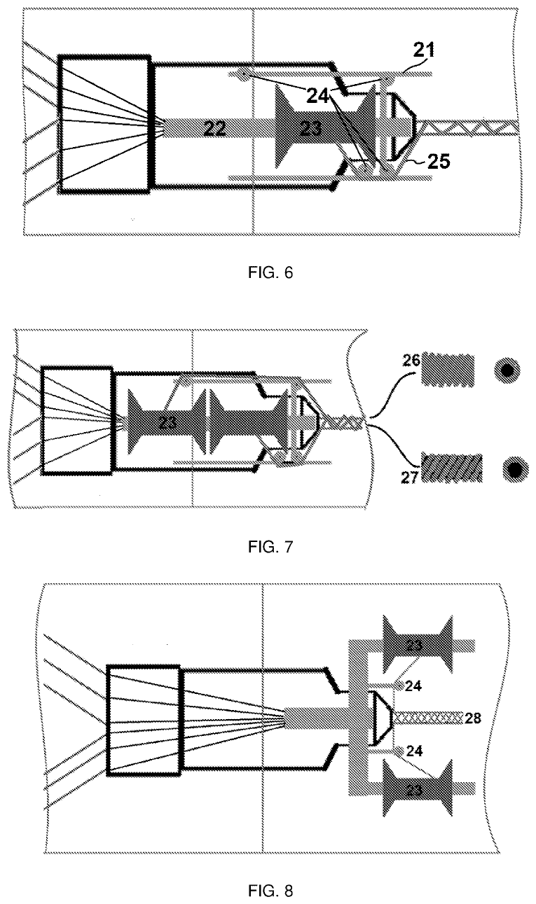

In this process, the wire(s) is wound on a solid bar formed by glass fibers, as previously presented. This occurs in sequence and in continuous mode. The coiling pitch (e.g. between 0.03 and 0.3 mm) and wire tension are controlled to meet the product specifications. The winding system, as shown in FIG. 6, is composed of a double or single Flyer (21) or even with larger quantities and also contains a duct/tube (22) for the passage of the fibers and assembly of the spool (23). In addition to this second reel, more reels could be added. Pulleys (24) are mounted on the Flyer to guide the coiled yarn (25) to the coiling rod. This system allows continuous winding with the possibility of increasing or decreasing the spacing between each turn according to the product's needs.

FIG. 7 shows a system similar to the one shown in FIG. 6, but with a second spool added (23)—in addition to this second spool more spools could be added. In the present winding stage, there is the capacity to manufacture coils in parallel, being able to have the coils stacked one on top of the other (26) or interspersed in the axial direction (27), just adding the corresponding number of spools and flyers, according to the number of coils in parallel—in (26) there are two stacked coils and in (27) there are two interleaved coils, but there can be more coils depending on the need of the product. In the case where the coils are stacked, between these coils material (e.g. polyester tape, epoxy resin, etc.) can be used for electrical insulation between the coils. For transformers, the application of this insulation is essential.

FIG. 8 presents an alternative to the system shown in FIGS. 6 and 7. A configuration in which the spools (23) travel around the bar of compacted fibers (28). The number of spools will depend on the project and can be added as required for winding with more than one reel in parallel. The wire is unwound from the spool according to consumption, guided by a set of pulleys (24) that can have the quantity and position modified according to the project's needs.

Regarding the process, the main difference between inductor and transformer is that the transformer must have more than 1 winding.

### Third Stage-Assembly and Fixing of the Terminals

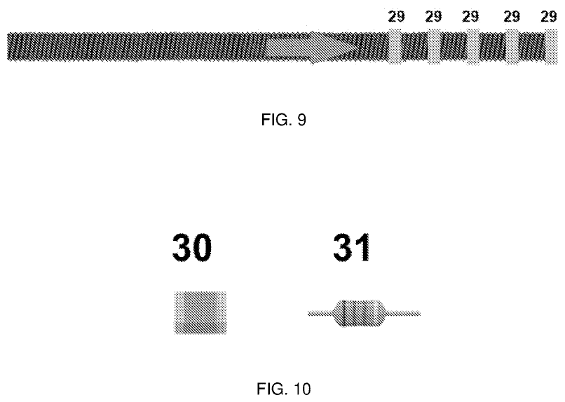

As shown in FIG. 9, after coiling, the bar goes to the assembly of the terminals (29) on its surface. Each product has terminals with spacing and quantity defined according to the design of the inductor/transformer. For example, each inductor has 2 terminals, but transformers have more than 2 terminals. During assembly, multiple terminals can be inserted per cycle into a bar larger than the length of an inductor or transformer. For the fixing of the terminals, different technologies can be used, for example, Micro Laser Soldering, Ultrasonic Soldering, TIG Soldering, Brazing with Tin and Conductive Adhesives or even a layer of tin (or other conductive material) at the ends of the inductor directly on the wound wire.

The design of the terminals may vary, examples are illustrated in FIG. 10.

Terminals can be compatible with the SMT (Surface-Mount Technology) (30) for mounting components on the surface of printed circuit boards, by the PTH (Pin Through Hole) method (31), or even some other as required by the project.

### Fourth Stage-Cutting and Testing of Continuity and Inductance

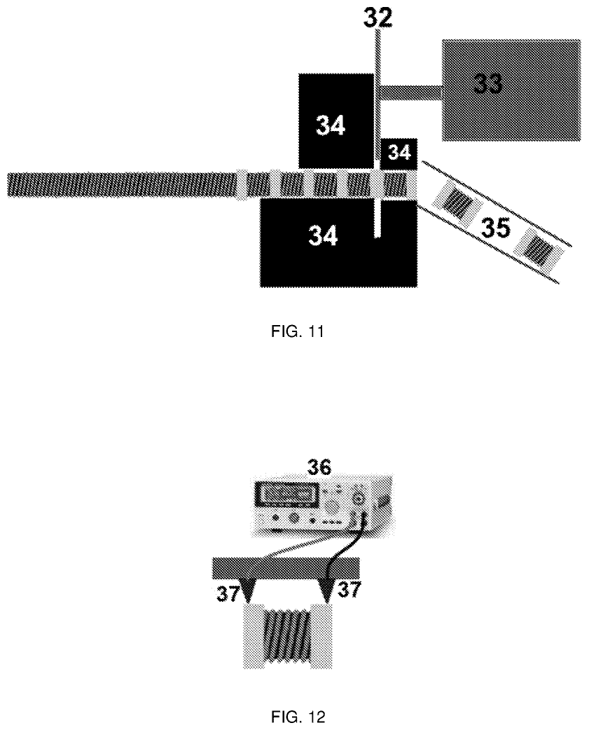

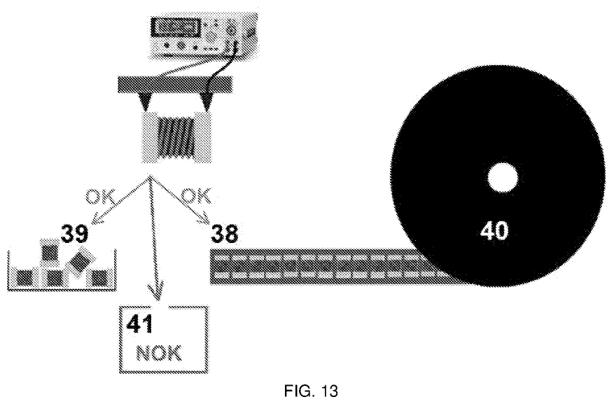

These processes occur immediately after the fixing of the terminals and not necessarily in this order. Cutting options are, for example, the use of discs (32) fixed to motors (33), or another system depending on the materials that make up the bar according to the project's needs. FIG. 11 shows an example of a cutting system composed of fasteners (34) that guide the bar and secure it during cutting. For example, the disc and motor assembly descends to perform the cut and then rises again. The clamp frees the jaws for a new cutting cycle. Cut parts can fall into a chute (35) and be, for example, picked up by an automatic manipulator, depending on the demand of the project. Depending on the customer's design or requirements, the inductor/transformer can be encapsulated with resin to result in an improvement in the picking process in the assembly lines of SMT components (devices that do not have terminals to be placed in holes), for example. Another point that can be inverted according to the product's needs is the cutting and fixing of the terminals after cutting, not detracting from the concept of the continuous process of production of inductors/transformers.

An LCR bridge (36) can be used for the continuity and inductance test, as illustrated in FIG. 12. The probes (37) must be sized and positioned at distances and quantities in order to meet the needs of each product (inductor or transformer) to be manufactured. The probes may be market items, or developed especially for the product under test and will be the interface between the product under test and the LCR bridge (36). The test stations can be replicated to meet productivity.

### Fifth Step-Packaging

The inductors or transformers that pass the tests will be packaged, for example, in conveyor tapes in plastic relief (38), or in bulk (39), or even develop some packaging according to customer requirements. In the case of using tapes, these are then wound onto spools (40). The parts that fail the test are discarded in a manhole (41) for later analysis, control of the scrap index and feedback of the cycle of improvements in the process. [023] It is important to emphasize that the figures and description made do not have the power to limit the forms of execution of the inventive concept proposed here, but rather to illustrate and make understandable the conceptual innovations revealed in this solution. Thus, the descriptions and images must be interpreted in an illustrative and non-limiting way, and there may be other equivalent or analogous ways of implementing the inventive concept revealed here and that do not escape the spectrum of protection outlined in the proposed solution.

What is claimed is:

1. A manufacturing process of inductors and transformers with continuous winding comprising the steps of:
I. Solid bar formation (1): through the compaction of glass fibers (6) impregnated with resin (7), with ejector nozzles (8), fixer applicators (resin/varnish) (9) and traction system (10); after impregnation and compaction, the wire is wound (11) continuously at the exit of the ejector nozzle (8), and then the bar with the wire goes through a curing process in the ovens (12);
II. Continuous Winding (2): the wire(s) is wound on a solid bar formed by glass fibers occurring in sequence and in continuous mode, with the winding system consisting of at least one double or single Flyer (21), a duct/tube (22) for the passage of fibers and assembly of at least one spool (23), and pulleys (24) are mounted on the Flyer to conduct the coiled wire (25) to the coiling rod;
III. Assembly and fixing of the Terminals (3): after coiling, the bar goes to the assembly of the terminals (29) on its surface;
IV. Cutting and Testing (4); occur soon after the fixing of the terminals (29), through the use of discs (32) fixed to motors (33);
V. Packaging (5): the inductors or transformers who pass the tests will be packed in plastic embossed conveyor tapes (38), or in bulk (39); and the parts that failed the test were discarded in a manhole (41) for later analysis, control of the scrap index and feedback of the cycle of improvements in the process.

2. The process of claim 1, wherein in step I) the traction system (10) is composed of a motor, gears and belts that drive the bar with a defined speed depending on the product to be manufactured.

3. The process of claim 1, wherein the fact that in step I) the temperatures of the furnaces (12) reached are preferably between 15° and 300° C., and may vary beyond these limits depending on the part to be manufactured.
